(19) United States
(12) Patent Application Publication
(10) Pub. No.: US 2014/0353770 A1
(43) Pub. Date: Dec. 4, 2014

(54) SEMICONDUCTOR DEVICE AND METHOD FOR FABRICATING THE SAME

(71) Applicant: PANASONIC CORPORATION, Osaka (JP)

(72) Inventor: Masayuki KAMEI, Toyama (JP)

(21) Appl. No.: 14/464,545

(22) Filed: Aug. 20, 2014

Related U.S. Application Data
(63) Continuation of application No. PCT/JP2013/001960, filed on Mar. 22, 2013.

(30) Foreign Application Priority Data
May 15, 2012 (JP) 2012-111874

(51) Int. Cl. H01L 29/78; H01L 29/417; H01L 21/266; H01L 29/66

(52) U.S. Cl. CPC H01L 29/7833; H01L 29/6659; H01L 29/41775; H01L 21/266
USPC 257/408; 438/305

(57) ABSTRACT

First sidewalls are provided on side surfaces of a gate electrode and on regions of a semiconductor substrate which are located on lateral sides of the gate electrode, second sidewalls are provided on the first sidewalls and each second sidewall has a height and a width respectively smaller than a height and a width of the first sidewall, outer sidewalls are provided outside the second sidewalls to cover the second sidewalls, and source and drain regions are provided in regions located on lateral sides of the outer sidewalls. The second sidewalls have a composition containing an atom causing a defect level due to a collision ion being implanted, and the first sidewalls and the third sidewalls have compositions containing no atom causing the defect level.

### CROSS-REFERENCE TO RELATED APPLICATIONS

This is a continuation of International Application No. PCT/JP2013/001960 filed on Mar. 22, 2013, which claims priority to Japanese Patent Application No. 2012-111874 filed on May 15, 2012. The entire disclosures of these applications are incorporated by reference herein.

### BACKGROUND

The present disclosure relates to semiconductor devices and methods for fabricating the same, specifically to a metal-insulator-semiconductor field effect transistor (MISFET) and a method for fabricating the same.

In recent years, charge coupled devices (CCD) which had been mainly used in the field of solid-state image sensing elements (image sensors) have been replaced with complementary metal insulator semiconductor (CMIS) sensors which are advantageous with regard to fabrication costs and electric power consumption. Fabrication steps of the CMIS sensor are highly consistent with processes for a system LSI. Thus, according to the miniaturization of the system LSI, the miniaturization of MISFETs included in a pixel sensor, for example, miniaturization in which each MISFET is downsized to have a gate length less than or equal to 1.5 μm and a gate width less than or equal to 0.5 μm has progressed in order to increase the integration density and the speed of the CMIS sensor.

In CMIS sensor fabricating processes based on a current system LSI processing technology, a gate electrode is formed, and then on side surfaces of the gate electrode, first sidewalls made of silicon oxide and each having an L-shaped cross section and second sidewalls made of silicon nitride allowing a contact-etch selectivity with respect to the silicon oxide are stacked (see, Japanese Unexamined Patent Publication No. 2008-085104).

### SUMMARY

With the above configuration, during implantation of impurity ions by using the second sidewalls and the first sidewalls as a mask to form the source and the drain, some of the ions collide with the second sidewalls and induce knock-on of nitrogen ions included in the second sidewalls, thereby displacing the nitrogen ions into a gate insulating film or to an interface between a semiconductor substrate and the gate insulating film, so that defects are formed. As a result, the formed defects serve as trap levels of carriers (electrons in the case of N channels, holes in the case of P channels), thereby increasing fluctuation of an output current of a MISFET.

Moreover, time fluctuation of the output current caused by the capture or emission of carriers moving between the source and the drain at defect levels at the interface between the gate insulating film and a surface of the semiconductor substrate, in-film defects in the gate insulating film, or the like increases in inverse proportion to a value of a ratio at which the channel area (gate length L×gate width W) of the MISFET is reduced. In the case of the CMIS sensor, the increase in fluctuation of the output current of the MISFET directly leads to an increase in noise, thereby degrading image characteristics.

This problem arises not only in CMIS sensors but also in miniaturized CMIS devices mounted to system LSIs and having a gate length of 90 nm or less.

In view of the foregoing, it is an object of the present disclosure to reduce fluctuation of an output current of a MISFET caused by ion implantation.

To achieve the above object, an example semiconductor device according to the present disclosure includes a semiconductor layer, a gate electrode provided on a gate insulating film on the semiconductor layer; first sidewalls selectively provided on side surfaces of the gate electrode and on regions of the semiconductor layer which are located on lateral sides of the gate electrode; second sidewalls provided on the first sidewalls to face the gate electrode and each having a height and a width respectively smaller than a height and a width of the first sidewall; third sidewalls provided outside the first sidewalls to cover the second sidewalls; and source and drain regions formed in regions of the semiconductor layer which are located on lateral sides of the third sidewalls, wherein the second sidewalls have a composition containing an atom causing a defect level due to a collision ion being implanted, and the first sidewalls and the third sidewalls have compositions containing no atom causing the defect level.

In the semiconductor device of the present disclosure, the atom causing the defect level may be a nitrogen atom.

In the semiconductor device of the present disclosure, the first sidewalls may each have an L-shaped cross section in a gate length direction.

In the semiconductor device of the present disclosure, the first sidewalls and the third sidewalls may be insulating films having identical compositions.

In the semiconductor device of the present disclosure, the first sidewalls and the third sidewalls may be insulating films having different compositions.

A first method for fabricating a semiconductor device according to the present disclosure includes: forming a gate electrode on a gate insulating film on a semiconductor layer; selectively forming first sidewalls on side surfaces of the gate electrode and on regions of the semiconductor layer which are located on lateral sides of the gate electrode; forming second sidewalls on the first sidewalls to face the gate electrode; selectively etching the second sidewalls to reduce a height and a width of each second sidewall to be smaller than a height and a width of the first sidewall; after the selectively etching the second sidewalls, forming third sidewalls outside the first sidewalls to cover the second sidewalls; forming source and drain regions by implanting impurity ions by using the first sidewalls and the third sidewalls as a mask into regions in the semiconductor layer which are located on lateral sides of the third sidewalls; and performing thermal treatment to activate the impurity ions implanted into the source and drain regions, wherein the second sidewalls have a composition containing an atom causing a defect level due to the implanted impurity ions, and the first sidewalls and the third sidewalls have compositions containing no atom causing the defect level.

A second method for fabricating a semiconductor device according to the present disclosure includes: forming a gate electrode on a gate insulating film on a semiconductor layer; selectively forming first sidewalls on side surfaces of the gate electrode and on regions of the semiconductor layer which are located on lateral sides of the gate electrode; forming second sidewalls on the first sidewalls to face the gate electrode; selectively etching the second sidewalls to reduce a height and a width of each second sidewall to be smaller than a height and a width of the first sidewall; after the selectively etching the second sidewalls, depositing an insulating film on the semiconductor layer to cover the first sidewalls and the second sidewalls; forming source and drain regions by implanting impurity ions into regions of the semiconductor layer which are located on lateral sides of the gate electrode by using the first sidewalls and parts of the insulating film covering the second sidewalls as a mask and through the insulating film; after the forming the source and drain regions, performing thermal treatment to activate the impurity ions implanted into the source and drain regions; after the performing the thermal treatment, forming the insulating film into third sidewalls covering the second sidewalls by performing whole area etching on the insulating film, wherein the second sidewalls have a composition containing an atom causing a defect level due to the implanted impurity ions, and the first sidewalls and the third sidewalls have compositions containing no atom causing the defect level.

According to the semiconductor device and the method for fabricating the same of the present disclosure, defects formed when source/drain regions are formed by ion implantation using stacked sidewalls as a mask are significantly reduced. As a result, fluctuation of an output current of the MISFET is reduced.

### BRIEF DESCRIPTION OF THE DRAWINGS

FIG. 1 is a cross-sectional view illustrating a semiconductor device according to an embodiment.

FIGS. 2A and 2B are cross-sectional views illustrating process steps of a method for fabricating the semiconductor device of the embodiment in a sequential order.

FIGS. 3A and 3B are cross-sectional views illustrating process steps of the method for fabricating the semiconductor device of the embodiment in a sequential order.

FIGS. 4A and 4B are cross-sectional views illustrating process steps of the method for fabricating the semiconductor device of the embodiment in a sequential order.

FIG. 5 is a cross-sectional view illustrating a process step of a method for fabricating a semiconductor device of a variation of the embodiment.

FIG. 6 is a graph illustrating results of evaluation of performance of the semiconductor device according to the embodiment compared with those of a conventional technique.

### DETAILED DESCRIPTION

### Embodiment

A semiconductor device and a method for fabricating the same according to an embodiment will be described with reference to the drawings. The drawings have been schematized to the extent that the shapes, sizes, positional relationship, etc. of elements are understandable. Thus, the present disclosure is not limited to those illustrated in the drawings. The specific materials, conditions, numerical conditions, etc. used in the following description are mere examples and are not intended to be limiting.

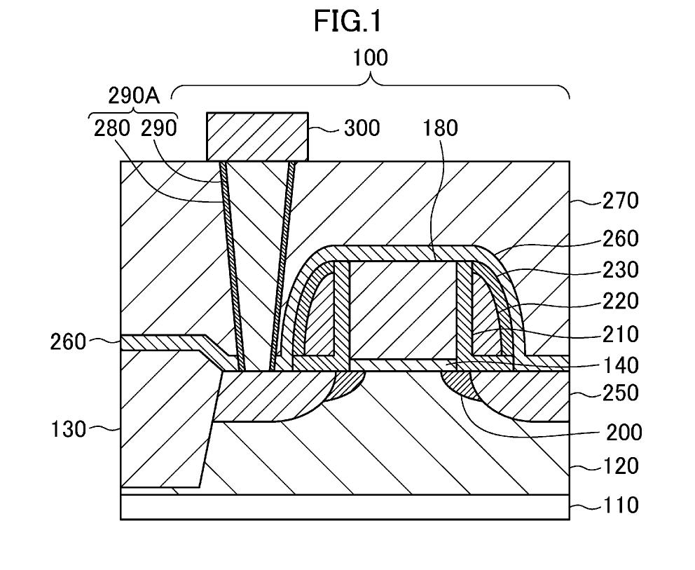

The semiconductor device according to the present embodiment will be described with reference to FIG. 1. FIG. 1 illustrates a cross-sectional structure of the semiconductor device according to the present embodiment. An n-type MIS field-effect transistor (NMISFET) provided in a solid-state image sensing device will be described as an example.

As illustrated in FIG. 1, the NMISFET is formed on a p-type well layer 120 and in an NMIS region 100. The p-type well layer 120 is obtained by implanting ions of, for example, boron (B) serving as a p-type impurity into a semiconductor substrate 110 made of silicon (Si). The NMIS region 100 is one of NMIS regions insulated and isolated from each other by an isolation film 130 such as shallow trench isolation (STI), local oxidation of silicon (LOCOS), etc.

On the p-type well layer 120, a 1-10-nm-thick gate insulating film 140 made of silicon oxide (SiO₂) is provided. On the gate insulating film 140, a gate electrode 180 is provided. The gate electrode 180 is made of polysilicon into which ions of, for example, arsenic (As) serving as an n-type impurity have been implanted. In regions of the p-type well layer 120 which are located under and on lateral sides of ends of the gate electrode 180, n-type lightly doped drain (LDD) regions 200 into which ions of, for example, arsenic (As) serving as an n-type LDD impurity have been implanted are provided.

First sidewalls 210 made of, for example, silicon oxide and each having an L-shaped cross section are provided on side surfaces of the gate electrode 180. A direction along which the cross section of the first sidewalls 210 is taken is the gate length direction of the gate electrode 180 (a lateral direction in the figure). On side surfaces and bottom surfaces of the first sidewall 210, second sidewalls 220 made of, for example, silicon nitride (SiN) are provided to face the gate electrode 180. The height and the width of each of the second sidewalls 220 are respectively smaller than the height and the width of the first sidewall 210. The height of the first sidewall 210 refers to a dimension in a direction perpendicular to a principal surface of the semiconductor substrate 110, and the width of the first sidewall 210 refers to a dimension in a direction parallel to the principal surface of the semiconductor substrate 110.

Outer sidewalls 230 serving as third sidewalls are made of, for example, silicon oxide to contact the first sidewalls 210 at upper end portions of the side surfaces of the first sidewalls 210 and at upper surfaces of outer portions of bottoms of the first side walls 210 and to cover the second sidewalls 220. Each outer sidewall 230 may have a thickness of about 10-30 nm.

In regions of the p-type well layer 120 which are located under and on lateral sides of the first sidewalls 210, the second sidewalls 220, and the outer sidewalls 230, n-type source/drain regions 250 into which ions of, for example, arsenic (As) serving as an n-type source/drain impurity have been implanted are provided.

An insulating film 260 serving as a contact-etch stopper and made of, for example, silicon nitride is provided to cover the gate electrode 180, the first sidewalls 210, the outer sidewalls 230, the n-type source/drain regions 250, and the isolation film 130. On the insulating film 260, an interlayer insulating film 270 having a high degree of embedding characteristics and being, for example, a chemical vapor deposition (CVD) oxide film is provided.

In the interlayer insulating film 270, a contact plug 290A is provided on the n-type source/drain region 250. The contact plug 290A extends through the interlayer insulating film 270 and the insulating film 260 and contacts the n-type source/drain region 250. On the interlayer insulating film 270, an interconnect 300 made of metal such as aluminum (Al) or copper (Cu) is provided to contact the contact plug 290A. Thus, the interconnect 300 is electrically connected to the n-type source/drain region 250 and the p-type well layer 120. The contact plug 290A includes a barrier metal film 280 made of, for example, titanium (Ti) or titanium nitride (TiN) and embedding metal 290 made of, for example, tungsten (W).

A contact plug 290A and an interconnect 300 which are not illustrated are electrically connected to the gate electrode 180, so that a desirable voltage can be applied to the gate electrode 180.

### Fabrication Method

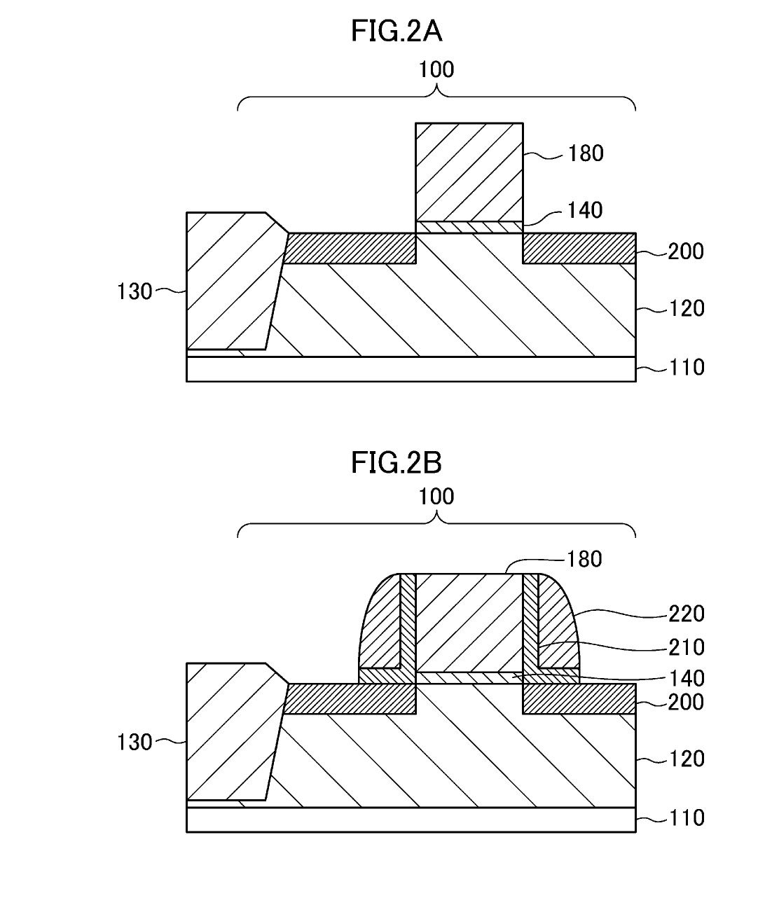

An example method for fabricating the semiconductor device according to the embodiment will be described with reference to FIGS. 2A, 2B, 3A, 3B, 4A, and 4B.

First, as illustrated in FIG. 2A, for example, boron (B) serving as a p-type impurity is selectively implanted into an upper portion of a semiconductor substrate 110 made of silicon at a dose of about 1×10¹²-1×10¹³/cm², thereby forming a p-type well layer 120.

Subsequently, an isolation film 130 such as STI or LOCOS is formed, thereby forming NMIS regions 100 isolated from each other.

Subsequently, on the semiconductor substrate 110, a gate insulating film 140 which is an about 1-10-nm-thick thermal oxide film and a gate electrode 180 made of about 80-150-nm-thick polysilicon 150 on the gate insulating film 140 are sequentially formed. Here, the thermal oxide film which is the gate insulating film 140 may be formed, for example, by an in situ steam generation (ISSG) method, a rapid thermal oxidation (RTO) method, or in an oxidation furnace. For example, arsenic (As) serving as an n-type impurity is implanted into the gate electrode 180 at a dose of about 1×10¹⁵/cm².

Subsequently, for example, arsenic (As) serving as an n-type LDD impurity is implanted by using the gate electrode 180 as a mask into regions in the p-type well layer 120 which are located on both sides of the gate electrode 180 at a dose of about 1×10¹²-1×10¹⁴/cm², thereby forming n-type LDD regions 200.

Next, on the entire surface of the semiconductor substrate 110, a 10-30-nm-thick first silicon oxide film and a 30-100-nm-thick silicon nitride film are sequentially formed. Subsequently, as illustrated in FIG. 2B, whole-area dry etching is performed on the first silicon oxide film and the silicon nitride film, thereby forming the first silicon oxide film into first sidewalls 210 each having an L-shaped cross section on side surfaces of the gate electrode 180 and forming the silicon nitride film into second sidewalls 220.

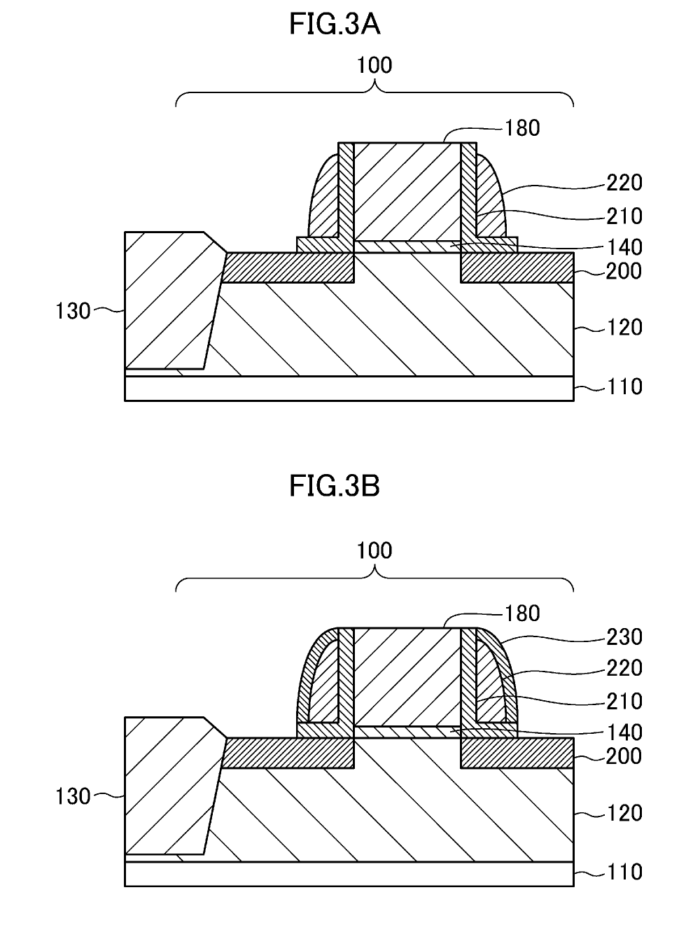

Next, as illustrated in FIG. 3A, the second sidewalls 220 made of silicon nitride are additionally etched for a short period of time, thereby reducing the thickness of the second sidewalls 220. In this way, the width and the height of each second sidewall 220 are respectively reduced by 10-30 nm than the width and the height of the first sidewall 210.

Next, a 10-30-nm-thick second silicon oxide film is formed on the entire surface of the semiconductor substrate 110. Subsequently, as illustrated in FIG. 3B, whole-area dry etching is performed on the second silicon oxide film, thereby forming the second silicon oxide film into outer sidewalls 230. Each outer sidewall 230 contacts the first sidewall 210 at an upper end portion of a side surface and an upper surface of an outer portion of a bottom of the first sidewall 210 having the L-shaped cross section.

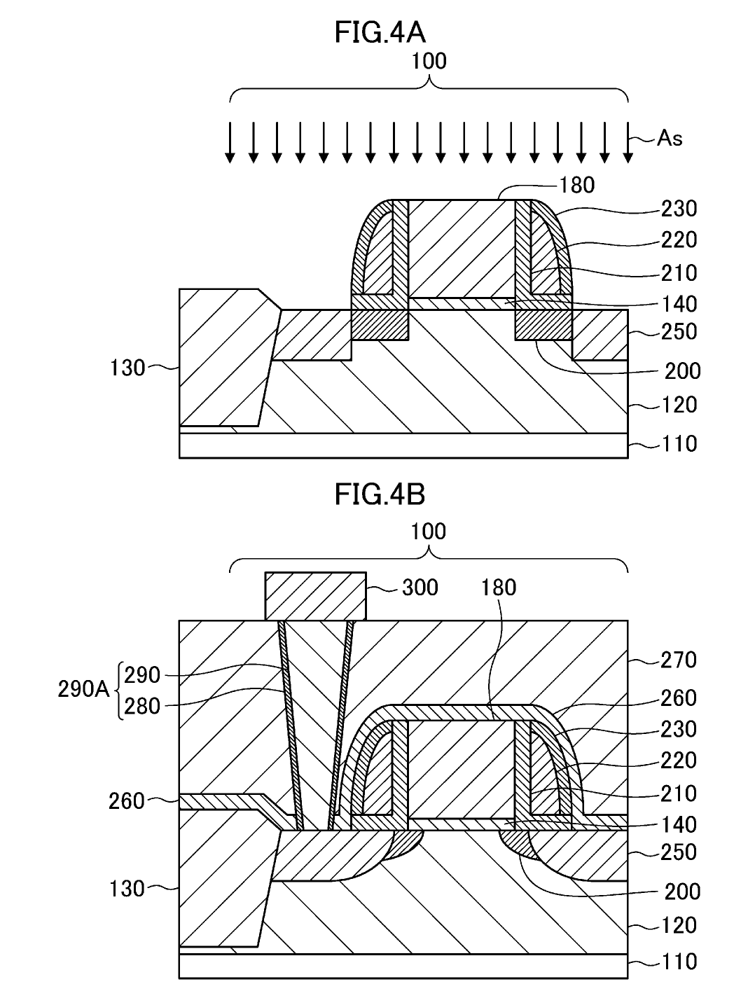

Next, as illustrated in FIG. 4A, ions of, for example, arsenic (As) serving as an n-type source/drain impurity are implanted at an accelerating voltage of about 20 keV and a dose of about 1×10¹⁵/cm² using the gate electrode 180, the first sidewalls 210 and the outer sidewalls 230 as a mask, thereby forming n-type source/drain regions 250 in regions in the p-type well layer 120 which are located on both sides of the first sidewalls 210 and the outer sidewalls 230.

Here, in the present embodiment, the second sidewalls 220 containing nitrogen atoms are covered with the third sidewalls 230 and the first sidewalls 210 which contain no nitrogen atom. Therefore, the ion implantation does not induce knock-on of the nitrogen atoms contained in the second sidewalls 220. In the present embodiment, the description “the first sidewalls 210 and the third sidewalls 230 which contain no nitrogen atom” means that no nitrogen atom is purposely added to the compositions of the sidewalls 210 and 230 in the formation of the sidewalls 210 and 230, but does not mean that the sidewalls 210 and 230 contain no residual nitrogen atom.

Next, as illustrated in FIG. 4B, thermal treatment is performed on the semiconductor substrate 110, thereby activating the impurity ions implanted into the n-type LDD regions 200 and the n-type source/drain regions 250 of the semiconductor substrate 110.

Subsequently, an insulating film 260 serving as a contact-etch stopper and made of silicon nitride is formed on the entire surface of the semiconductor substrate 110, that is, to cover the gate electrode 180, the first sidewalls 210, the outer sidewalls 230, the n-type source/drain regions 250, and the isolation film 130.

Subsequently, an interlayer insulating film 270 is formed on the insulating film 260 by a known technique, for example, by CVD. Then, an upper surface of the interlayer insulating film 270 is planarized by chemical mechanical polishing (CMP), or the like. Subsequently, a contact hole is selectively formed by lithography and etching so that the n-type source/drain region 250 is exposed in the contact hole. Then, a 3-10-nm-thick barrier metal film 280 is formed on a wall surface of the contact hole, and the contact hole is subsequently filled with embedding metal 290, thereby forming a contact plug 290A. Then, a metal film is deposited on the interlayer insulating film by sputtering or plating. Subsequently, the metal film is patterned by lithography and etching so that the metal film contacts the contact plug 290A, thereby forming an interconnect 300.

As described above, for example, titanium (Ti) or titanium nitride (TiN) can be used as the barrier metal film 280. For example, tungsten (W) can be used as the embedding metal 290. Aluminum (Al) or copper (Cu) can be used as the metal film for the interconnect 300. Although not shown, another contact plug 290A electrically connected to the gate electrode 180 is simultaneously formed.

### Variation of Embodiment

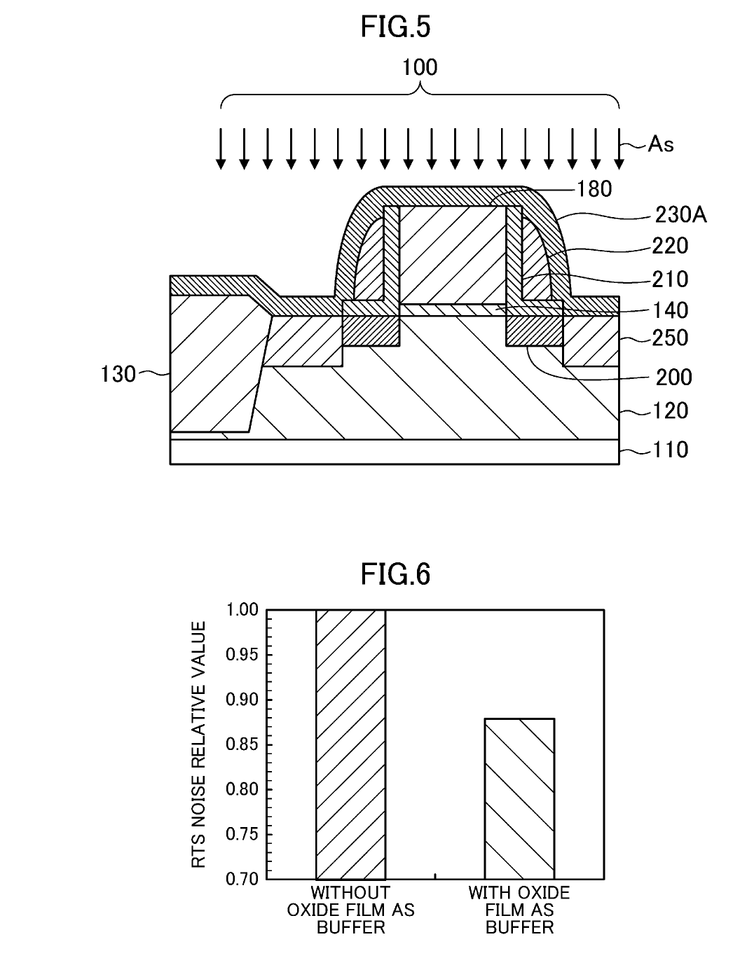

With reference the FIG. 5, a variation of the method for fabricating the semiconductor device according to the present embodiment will be described below.

In the step of implanting ions to form the n-type source/drain regions 250 illustrated in FIG. 4A, the outer sidewalls 230 have been patterned.

In the present variation, as illustrated in FIG. 5, before an insulating film 230A from which outer sidewalls 230 will be formed are patterned into sidewalls, ions of an impurity such as As are implanted through the insulating film 230A, thereby forming n-type source/drain regions 250.

Thermal treatment to activate impurity ions implanted into n-type LDD regions 200 and the n-type source/drain regions 250 may be performed after the n-type source/drain regions 250 are formed.

Then, whole-area dry etching is performed on the insulating film 230A, thereby forming the insulating film 230A into the outer sidewalls 230 corresponding to those in FIG. 4B.

As described above, in the MISFET according to the present embodiment and the variation of the embodiment, when the n-type source/drain impurity is implanted, the second sidewalls 220 provided on both the side surfaces of the gate electrode 180 and made of silicon nitride are covered with the outer sidewalls 230 or the insulating film 230A made of silicon oxide. Thus, the outer sidewalls 230 or the insulating film 230A made of silicon oxide serve as buffers, and thus ions of the n-type source/drain impurity do not directly collide with the silicon nitride film forming the second sidewalls 220. This reduces displacement of knock-on nitrogen atoms into the gate insulating film 140 or to the interface between the semiconductor substrate 110 and the gate insulating film 140, the knock-on nitrogen atoms being induced by implantation of the ions of the n-type source/drain impurity into the silicon nitride film. Thus, defects formed by the knock-on nitrogen atoms are reduced. As a result, fluctuation of an output current is reduced, the fluctuation being caused by a capture process and an emission process of carriers moving between the n-type source drain of the MISFET at defects due to the knock-on nitrogen atoms.

FIG. 6 is a graph illustrating random telegraph signal (RTS) noise which is time fluctuation of an output current of a MISFET in comparison between a conventional technique and the present disclosure. As illustrated in FIG. 6, in the present disclosure, a silicon oxide film for buffering collision of implanted ions in implanting an n-type source/drain impurity is provided on surfaces of the second sidewalls 220. It can be seen that the silicon oxide film reduces the RTS noise by 10% or more compared to that in the case of the conventional technique.

The second sidewalls 220 made of silicon nitride having a relative dielectric constant generally about two times as high as that of silicon oxide are recessed by additional etching, and are covered with the outer sidewalls 230 made of silicon oxide. Therefore, the fringe capacitance between the gate electrode 180 and the n-type source/drain regions 250 is reduced, so that a delay in speed due to the MISFET is also reduced.

In the present embodiment and the variation of the embodiment, silicon oxide is used as both the first sidewalls 210 and the outer sidewalls 230. However, as long as the first sidewalls 210 and the outer sidewalls 230 contain no nitrogen atom, they are not limited to silicon oxide. Thus, insulating films having different compositions may be used as the first sidewalls 210 and the outer sidewalls 230. For example, the first sidewalls 210 or the outer sidewalls 230 may be made of sapphire (Al₂O₃), for example. The second sidewalls 220 are not necessarily limited to silicon nitride (SiN). That is, in the step illustrated in FIG. 2B, the second sidewall 220 can be made of a material having an etching rate different from the etching rate of the first sidewall 210 and having a composition in which defect levels are caused by knock-on atoms induced by impurity ions in forming the source/drain regions 250. Thus, for example, titanium oxide (TiO₂) can be used as the second sidewalls.

Although in the present embodiment, a method for fabricating an n-type MIS field-effect transistor (NMISFET) has been described as an example, the method is applicable to a p-type MIS field-effect transistor (PMISFET) when an n-type well layer is formed on a semiconductor substrate, and the types impurities to be implanted into a low concentration impurity diffusion layer (LDD regions), a high concentration impurity diffusion layer (source/drain regions), and a polysilicon film (gate electrode) are changed from n to p.

Although in the present embodiment, a MISFET in a CMIS sensor has been described as a semiconductor device, similar advantages can be obtained not only in CMIS sensors, but also in miniaturized CMIS devices mounted to system LSIs and having a gate length of, for example, 90 nm or less.

The semiconductor device according to the present disclosure and a method for fabricating the same are useful for, for example, MIS-type field-effect transistors in which source drain implantation is performed through sidewalls and methods for fabricating the same.

What is claimed is:

1. A semiconductor device comprising:
a semiconductor layer,
a gate electrode provided on a gate insulating film on the semiconductor layer;
first sidewalls selectively provided on side surfaces of the gate electrode and on regions of the semiconductor layer which are located on lateral sides of the gate electrode;
second sidewalls provided on the first sidewalls to face the gate electrode and each having a height and a width respectively smaller than a height and a width of the first sidewall;
third sidewalls provided outside the first sidewalls to cover the second sidewalls; and
source and drain regions formed in regions of the semiconductor layer which are located on lateral sides of the third sidewalls, wherein
the second sidewalls have a composition containing an atom causing a defect level due to a collision ion being implanted,
the second sidewalls do not contain the collision ion, and
the first sidewalls and the third sidewalls have compositions containing no atom causing the defect level.

2. The semiconductor device of claim 1, wherein
the collision ion is an impurity ion for forming the source and drain regions.

3. The semiconductor device of claim 1, wherein
the atom causing the defect level is a nitrogen atom.

4. The semiconductor device of claim 1, wherein
the first sidewalls each have an L-shaped cross section in a gate length direction.

5. The semiconductor device of claim 1, wherein
the first sidewalls and the third sidewalls are insulating films having identical compositions.

6. The semiconductor device of claim 1, wherein
the first sidewalls and the third sidewalls are insulating films having different compositions.

7. A method for fabricating a semiconductor device, the method comprising:
forming a gate electrode on a gate insulating film on a semiconductor layer;
selectively forming first sidewalls on side surfaces of the gate electrode and on regions of the semiconductor layer which are located on lateral sides of the gate electrode;
forming second sidewalls on the first sidewalls to face the gate electrode;
selectively etching the second sidewalls to reduce a height and a width of each second sidewall to be smaller than a height and a width of the first sidewall;
after the selectively etching the second sidewalls, forming third sidewalls outside the first sidewalls to cover the second sidewalls;
forming source and drain regions by implanting impurity ions by using the first sidewalls and the third sidewalls as a mask into regions in the semiconductor layer which are located on lateral sides of the third sidewalls; and
performing thermal treatment to activate the impurity ions implanted into the source and drain regions, wherein
the second sidewalls have a composition containing an atom causing a defect level due to the implanted impurity ions,
the second sidewalls do not contain the impurity ions, and
the first sidewalls and the third sidewalls have compositions containing no atom causing the defect level.

8. The method of claim 7, wherein
the atom causing the defect level is a nitrogen atom.

9. A method for fabricating a semiconductor device, the method comprising:
forming a gate electrode on a gate insulating film on a semiconductor layer;
selectively forming first sidewalls on side surfaces of the gate electrode and on regions of the semiconductor layer which are located on lateral sides of the gate electrode;
forming second sidewalls on the first sidewalls to face the gate electrode;
selectively etching the second sidewalls to reduce a height and a width of each second sidewall to be smaller than a height and a width of the first sidewall;
after the selectively etching the second sidewalls, depositing an insulating film on the semiconductor layer to cover the first sidewalls and the second sidewalls;
forming source and drain regions by implanting impurity ions into regions of the semiconductor layer which are located on lateral sides of the gate electrode by using the first sidewalls and parts of the insulating film covering the second sidewalls as a mask and through the insulating film;
after the forming the source and drain regions, performing thermal treatment to activate the impurity ions implanted into the source and drain regions;
after the performing the thermal treatment, forming the insulating film into third sidewalls covering the second sidewalls by performing whole area etching on the insulating film, wherein
the second sidewalls have a composition containing an atom causing a defect level due to the implanted impurity ions, and
the first sidewalls and the third sidewalls have compositions containing no atom causing the defect level.

10. The method of claim 9, wherein
the second sidewalls do not contain the impurity ions.

11. The method of claim 9, wherein
the atom causing the defect level is a nitrogen atom.
